(19) United States
(12) Patent Application Publication
(10) Pub. No.: US 2010/0294339 A1
(43) Pub. Date: Nov. 25, 2010

(54) photovoltaic device with a luminescent down-shifting material

(75) Inventor: Dennis Hollars, San Jose, CA (US)

Correspondence Address: The Marbury Law Group, PLLC, 11800 Sunrise Valley Drive, Suite 1000, Reston, VA, 20191, US

(73) Assignee: Miasole

(21) Appl. No.: 12/733,257

(22) PCT Filed: Jul. 11, 2008
(86) PCT No.: PCT/US08/08513

§ 371 Date: Feb. 19, 2010

Related U.S. Application Data
(60) Provisional application No. 60/950,161, filed on Jul. 17, 2007.

(51) Int. Cl. H01L 31/12; H01L 31/02

(52) U.S. Cl. 136/247; 136/257

(57) ABSTRACT

A photovoltaic cell includes a photovoltaic material disposed between front and back side electrodes, an insulating layer disposed on the front side electrode and one or more luminescent down shifting materials. Also provided is a photovoltaic module that includes a first photovoltaic cell, a second photovoltaic cell, one or more luminescent down shifting materials and a collector-connector configured to collect current from the first photovoltaic cell and to electrically connect the first photovoltaic cell with the second photovoltaic cell.

### CROSS-REFERENCE TO RELATED PATENT APPLICATIONS

The present application claims benefit of U.S. patent application 60/950,161, filed Jul. 17, 2007, which is incorporated herein by reference in its entirety.

### FIELD

The present invention relates generally to photovoltaic devices and more particularly to photovoltaic devices utilizing luminescence down-shifting materials.

### BACKGROUND

Commercially produced photovoltaic modules can exhibit poor external quantum efficiencies at short wavelengths. It is desirable to develop photovoltaic devices that can overcome this drawback of the commercial photovoltaic modules.

### SUMMARY

According to one embodiment, a photovoltaic cell comprises (a) a front side electrode; (b) a back side electrode; (c) a photovoltaic material having a first side and a second side, the photovoltaic material being disposed between the front side electrode and the back side electrode such that the first side faces the front side electrode and the second side faces the back side electrode; (d) an insulating layer disposed over the front side electrode, and (e) one or more luminescence down shifting materials facing the first side of the photovoltaic material. According to another embodiment, a photovoltaic module comprises a first photovoltaic cell; a second photovoltaic cell; and a collector-connector that comprises an insulating carrier and at least one conductor and that is configured to collect current from the first photovoltaic cell and to electrically connect the first photovoltaic cell with the second photovoltaic cell, wherein at least one of the first photovoltaic cell and the second photovoltaic cell comprises one or more luminescence down shifting material.

### BRIEF DESCRIPTION OF THE DRAWINGS

FIG. 1 schematically depicts a photovoltaic cell with an insulating layer on a front side electrode.

FIG. 2 schematically illustrates a photovoltaic module that includes two photovoltaic cells and a flexible collector-connector.

FIGS. 3A and 3B schematically illustrate a photovoltaic module that includes two photovoltaic cells and a flexible collector-connector.

FIG. 4 schematically illustrates a photovoltaic module that includes a plurality of photovoltaic cells.

FIG. 5 is a photograph of a flexible Cu(In,Ga)Se₂ (CIGS) cell formed on flexible stainless steel substrate.

FIG. 6 is a photograph illustrating a flexible nature of CIGS cell formed on flexible stainless steel substrate.

### DETAILED DESCRIPTION

Unless otherwise specified, “a” or “an” means one or more.

The invention relates to a photovoltaic device that utilizes one or more luminescence down shifting materials that can absorb short wavelength photons and reemit them at a longer wavelength and thus increase the efficiency of the photovoltaic device.

### Photovoltaic Cell

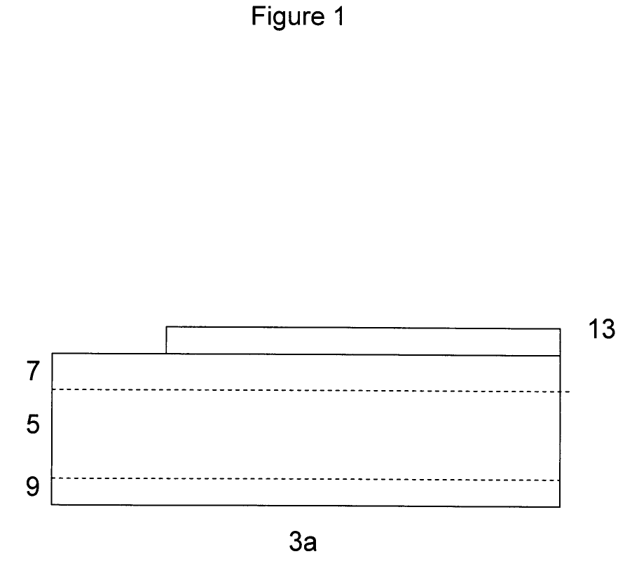

According to one embodiment, the photovoltaic device is a photovoltaic cell comprising one or more luminescent down shifting materials. FIG. 1 illustrates such a photovoltaic cell that besides one or more luminescent down shifting materials also includes a front side electrode 7, a back side electrode 9, a photovoltaic material 5 and an insulating layer 13.

The photovoltaic material 5 can be a semiconductor material. For example, the photovoltaic material may comprise a p-n or p-i-n junction in a Group IV semiconductor material, such as amorphous or crystalline silicon, a Group II-VI semiconductor material, such as CdTe or CdS, a Group I-III-VI semiconductor material, such as CuInSe₂ (CIS) or Cu(In,Ga)Se₂ (CIGS), and/or a Group III-V semiconductor material, such as GaAs or InGaP. The p-n junctions may comprise heterojunctions of different materials, such as CIGS/CdS heterojunction, for example. The electrodes 7, 9 can be designated as first and second polarity electrodes since electrodes have an opposite polarity. For example, the front side electrode 7 may be electrically connected to an n-side of a p-n junction and the back side electrode may be electrically connected to a p-side of a p-n junction. The electrode 7 on the front surface of the cell may be an optically transparent front side electrode which is adapted to face the Sun, and may comprise a transparent conductive material, such as indium tin oxide or aluminum doped zinc oxide.

The electrode 9 on the back surface of the cell may be a back side electrode, which is adapted to face away from the Sun, and may comprise one or more conductive materials such as copper, molybdenum, aluminum, stainless steel and/or alloys thereof. This electrode 9 may also comprise a substrate upon which the photovoltaic material 5 and the front electrode 7 are deposited during fabrication of the cell. The electrode 9 can be flexible.

The insulating layer 13 can comprise a polymer. For example, the insulating carrier can comprise a flexible, electrically insulating polymer film having a sheet or ribbon shape. Examples of suitable polymer materials include thermal polymer olefin (TPO). TPO includes any olefins which have thermoplastic properties, such as polyethylene, polypropylene, polybutylene, etc. Other polymer materials which are not significantly degraded by sunlight, such as EVA, other non-olefin thermoplastic polymers, such as fluoropolymers, acrylics or silicones, as well as multilayer laminates and co-extrusions, such as PET/EVA laminates or co-extrusions, may also be used. The insulating layer 13 may also comprise any other electrically insulating material, such as glass or ceramic materials. The layer 13 may be a sheet or ribbon which is unrolled from a roll or spool. The layer 13 may also have other suitable shapes besides sheet or ribbon shape.

One or more luminescent down shifting material(s) is disposed in the photovoltaic cell in such a manner that a light, such as a light from the Sun, passes through these material(s) on the way to the photovoltaic material. In other words, the one or more luminescence down shifting materials face the same side of the photovoltaic material as the front side electrode.

Thus, the luminescence down shifting material can be incorporated in the insulating layer 13 or disposed between the insulating layer 13 and the front side electrode 7. The luminescence down shifting material can be also disposed on the top of the front side electrode 7 or on the top of the insulating layer 13. When more than one insulating layers 13 are used as discussed below, the luminescence down shifting material can be disposed between the insulating layers.

Particular luminescent down shifting material(s) for the photovoltaic cell of the invention are selected depending on a spectral dependence of an external quantum efficiency for a photovoltaic cell that has all the elements of the photovoltaic cell of the invention but does not contain any luminescent down shifting materials. For brevity, such a cell that does not contain any luminescent down shifting materials (LDSM) will be referred to as a no-LDSM cell. The no-LDSM cell has a threshold wavelength of the no-LDSM cell, i.e. a wavelength, below which the efficiency of the no-LDSM cell is low or poor and immediately above which, the efficiency of the no-LDSM cell is high. The luminescent down shifting material(s) are selected to such that they absorb a light at wavelengths below the threshold wavelength of the no-LDSM cell and reemit a light at wavelengths, where the efficiency of the no-LDSM cell is high. The luminescent down shifting material(s) can be selected to be such that they absorb all the wavelengths starting from around 300 nm up to the threshold wavelength of the no-LDSM cell, such as, for example, 400 nm for the CIGS no-LDSM cell. Preferably, but not necessarily, the luminescent down shifting material(s) are selected to be such that they absorb all the wavelengths of the Sunlight passing through the atmosphere starting from around 200 nm up to the threshold wavelength of the no-LDSM cell. Preferably, none of the selected luminescence down shifting material(s) absorbs light at wavelengths, at which the external quantum efficiency of the no-LDSM cell is high. The selected luminescence down shifting material with the longest emission wavelength has an emission peak in the spectral region, where the external quantum efficiency of the no-LDSM cell is high.

Multiple luminescence down shifting materials can be selected to be such that an absorption region of one of the selected materials overlaps with an emission region of another of the selected materials. For example, luminescent down shifting materials can include from two or more materials selected from a violet dye (peak emission wavelength between 400 and 450 nm), blue dye (peak emission wavelength between 450 and 500 nm), green dye (peak emission wavelength between 500 and 560 nm), yellow dye (peak emission wavelength between 560 and 585 nm), orange dye (peak emission wavelength between 585 and 620 nm) and red dye (peak emission wavelength between 585 and 700 nm). The use of multiple luminescence down shifting materials for in photovoltaic cells is discussed, for example, in Bryce S. Richards and Keith R. McIntosh, “Enhancing the efficiency of production CdS/CdTe PV modules by overcoming poor spectral response at short wavelengths via luminescence downshifting”, IEEE 4th World Conference on Photovoltaic Energy Conversion, Hawaii, May 2006, and in Keith R. McIntosh and Bryce S. Richards, “Increased mc-Si module efficiency using fluorescent organic dyes: a ray-tracing study”, IEEE 4th World Conference on Photovoltaic Energy Conversion, Hawaii, May 2006, which are both incorporated herein by reference in their entirety. For a double combination, a violet dye, such as Lumogen® Violet570, can be combined with a yellow dye, such as Lumogen® Yellow083. Such a combination can absorb wavelengths in the absorption regions of both violet and yellow dyes and reemit the light in the emission region of the yellow dye. In other words, the violet dye absorbs incident ultraviolet radiation and emits violet light. The yellow dye absorbs the violet light and emits yellow light which is incident on the photovoltaic cell. Another example of a double combination can be a combination of a yellow dye, such as Lumogen® Yellow083, and an orange dye, such as Lumogen® Orange240. Such a combination can absorb wavelengths in the absorption regions of both orange and yellow dyes and reemit the light in the emission region of the orange dye.

Another example of a double combination is an orange dye, such as Lumogen® Orange240, combined with a red dye, such as Lumogen® Red300. Such a combination can absorb wavelengths in the absorption regions of both orange and red dyes and reemit the light in the emission region of the red dye.

For a triple combination, a violet dye, such as Lumogen® Violet570, can be combined with a yellow dye, such as Lumogen® Yellow083 and an orange dye, such as Lumogen® Orange240. Such a triple combination can absorb wavelengths in the absorption regions of all three of violet, yellow and orange dyes and reemit the light in the emission region of the orange dye. A suitable triple combination can be also formed by a yellow dye, such as Lumogen® Yellow083, an orange dye, such as Lumogen® Orange240, and a red dye, such as Lumogen® Red300. Such a triple combination can absorb the light in the absorption regions of all three of the yellow, orange and red dyes and reemit the light in the emission region of the red dye.

A quadruple combination can be formed by a violet dye, such as Lumogen® Violet570, a yellow dye, such as Lumogen® Yellow083, an orange dye, such as Lumogen® Orange240, and a red dye, such as Lumogen® Red300. Such a combination will absorb the light in the absorption regions of all four of the violet, yellow, orange and red dyes and reemit the light in the emission region of the red dye. The dyes can be mixed together in a single layer which may also comprise an optically transparent binder material. Alternatively, the dyes may be located in stacked, separate, adjacent layers. For example, the dye(s) which emit at a longer wavelength may be located closes to the photovoltaic cell than the dye(s) which emit at a shorter wavelength.

The luminescent down shifting materials can include organic materials, inorganic materials or a combination of the two. Preferably, each of the luminescent down shifting materials is a luminescent material with luminescence quantum efficiency of at least 90% and more preferably of at least 93%.

Examples of organic luminescent down shifting materials include organic fluorescent dyes, such as, for example, naphthalene and perylene dyes. Certain naphthalene and perylene dyes are distributed by BASF as Lumogen® fluorescent dyes. Examples of Lumogen® fluorescent dyes include 1,7-bis(isobutyloxycarbonyl)-6,12-dicyanoperylene (Lumogen® Yellow083), perylenetetracarboxylic diimide fluorescent dyes (Lumogen® Red300 and Lumogen® Orange240) and 4,5-dimethoxy-N-2-ethylhexyl-1-naphtylimide (Lumogen® Violet570).

Examples of inorganic luminescent down shifting materials include phosphor materials, such as ceramic materials containing optically active activator ions, which are listed in S. Shionoya and W. M. Yen (eds) “Phosphor Handbook”, CRC Press, 1998, incorporated herein by reference in its entirety.

### Photovoltaic Module

According to another embodiment, the photovoltaic device can be a photovoltaic module that includes at least two photovoltaic cells, a collector-connector and one or more luminescent downshifting materials in at least one of the photovoltaic cells. At least one of the photovoltaic cells can be a photovoltaic cell of the first embodiment described above. Preferably, each of the photovoltaic cells in the module is a photovoltaic cell of the first embodiment.

As used herein, the term “module” includes an assembly of at least two, and preferably three or more electrically interconnected photovoltaic cells, which may also be referred to as “solar cells”. The “collector-connector” is a device that acts as both a current collector to collect current from at least one photovoltaic cell of the module, and as an interconnect which electrically interconnects the at least one photovoltaic cell with at least one other photovoltaic cell of the module. In general, the collector-connector takes the current collected from each cell of the module and combines it to provide a useful current and voltage at the output connectors of the module.

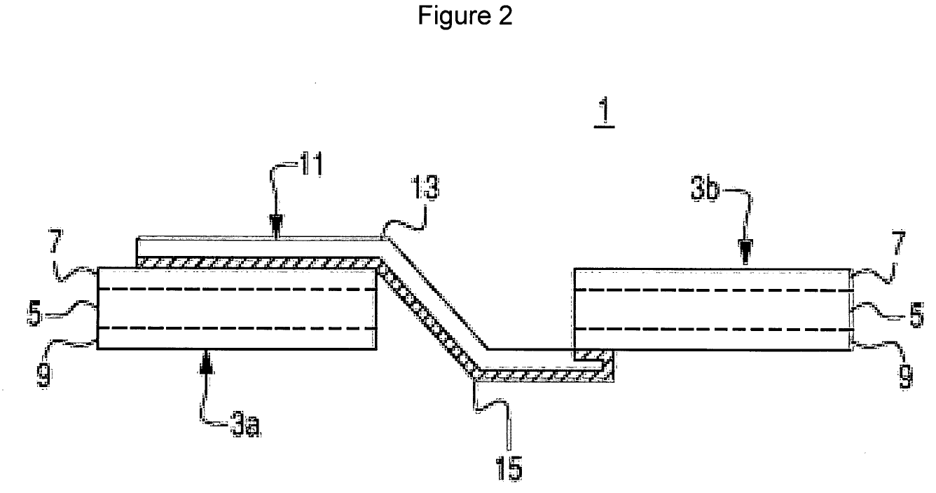

FIG. 2 schematically illustrates a module 1. The module 1 includes first and second photovoltaic cells 3a and 3b. It should be understood that the module 1 may contain three or more cells, such as 3-10,000 cells for example. Preferably, the first 3a and the second 3b photovoltaic cells are plate shaped cells which are located adjacent to each other, as shown schematically in FIG. 2. The cells may have a square, rectangular (including ribbon shape), hexagonal or other polygonal, circular, oval or irregular shape when viewed from the top.

The module contains the collector-connector 11, which comprises an electrically insulating carrier 13 and at least one electrical conductor 15. The collector-connector 11 electrically contacts the first polarity electrode 7 of the first photovoltaic cell 3a in such a way as to collect current from the first photovoltaic cell. For example, the electrical conductor 15 electrically contacts a major portion of a surface of the first polarity electrode 7 of the first photovoltaic cell 3a to collect current from cell 3a. The conductor 15 portion of the collector-connector 11 also electrically contacts the second polarity electrode 9 of the second photovoltaic cell 3b to electrically connect the first polarity electrode 7 of the first photovoltaic cell 3a to the second polarity electrode 9 of the second photovoltaic cell 3b.

Preferably, the carrier 13 comprises a flexible, electrically insulating polymer film having a sheet or ribbon shape, supporting at least one electrical conductor 15. Examples of suitable polymer materials include thermal polymer olefin (TPO). TPO includes any olefins which have thermoplastic properties, such as polyethylene, polypropylene, polybutylene, etc. Other polymer materials which are not significantly degraded by sunlight, such as EVA, other non-olefin thermoplastic polymers, such as fluoropolymers, acrylics or silicones, as well as multilayer laminates and co-extrusions, such as PET/EVA laminates or co-extrusions, may also be used. The insulating carrier 13 may also comprise any other electrically insulating material, such as glass or ceramic materials. The carrier 13 may be a sheet or ribbon which is unrolled from a roll or spool and which is used to support conductor(s) 15 which interconnect three or more cells 3 in a module 1. The carrier 13 may also have other suitable shapes besides sheet or ribbon shape.

The conductor 15 may comprise any electrically conductive trace or wire. Preferably, the conductor 15 is applied to an insulating carrier 13 which acts as a substrate during deposition of the conductor. The collector-connector 11 is then applied in contact with the cells 3 such that the conductor 15 contacts one or more electrodes 7, 9 of the cells 3. For example, the conductor 15 may comprise a trace, such as silver paste, for example a polymer-silver powder mixture paste, which is spread, such as screen printed, onto the carrier 13 to form a plurality of conductive traces on the carrier 13. The conductor 15 may also comprise a multilayer trace. For example, the multilayer trace may comprise a seed layer and a plated layer. The seed layer may comprise any conductive material, such as a silver filled ink or a carbon filled ink which is printed on the carrier 13 in a desired pattern. The seed layer may be formed by high speed printing, such as rotary screen printing, flat bed printing, rotary gravure printing, etc. The plated layer may comprise any conductive material which can by formed by plating, such as copper, nickel, cobalt or their alloys. The plated layer may be formed by electroplating by selectively forming the plated layer on the seed layer which is used as one of the electrodes in a plating bath. Alternatively, the plated layer may be formed by electroless plating. Alternatively, the conductor 15 may comprise a plurality of metal wires, such as copper, aluminum, and/or their alloy wires, which are supported by or attached to the carrier 13. The wires or the traces 15 electrically contact a major portion of a surface of the first polarity electrode 7 of the first photovoltaic cell 3a to collect current from this cell 3a. The wires or the traces 15 also electrically contact at least a portion of the second polarity electrode 9 of the second photovoltaic cell 3b to electrically connect this electrode 9 of cell 3b to the first polarity electrode 7 of the first photovoltaic cell 3a. The wires or traces 15 may form a grid-like contact to the electrode 7. The wires or traces 15 may include thin gridlines as well as optional thick busbars or buslines. If busbars or buslines are present, then the gridlines may be arranged as thin “fingers” which extend from the busbars or buslines.

The module containing a collector-connector provides a current collection and interconnection configuration and method that is less expensive, more durable, and allows more light to strike the active area of the photovoltaic module than the prior art modules. The module provides collection of current from a photovoltaic (“PV”) cell and the electrical interconnection of two or more PV cells for the purpose of transferring the current generated in one PV cell to adjacent cells and/or out of the photovoltaic module to the output connectors. In addition, the carrier is may be easily cut, formed, and manipulated. In addition, when interconnecting thin-film solar cells with a metallic substrate, such as stainless steel, the embodiments of the invention allow for a better thermal expansion coefficient match between the interconnecting solders used and the solar cell than with traditional solder joints on silicon PV cells)

In particular, the cells of the module may be interconnected without using soldered tab and string interconnection techniques of the prior art. However, soldering may be used if desired.

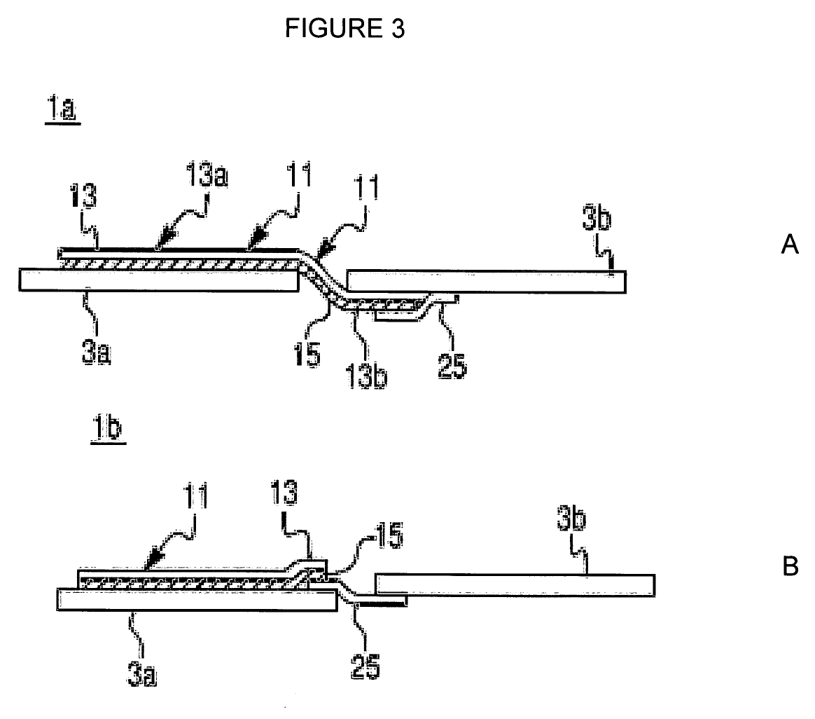

FIGS. 3A and 3B illustrate modules 1a and 1b, respectively, in which the carrier film 13 contains conductive traces 15 printed on one side. The traces 15 electrically contact the active surface of cell 3a (i.e., the front electrode 7 of cell 3a) collecting current generated on that cell 3a. A conductive interstitial material may be added between the conductive trace 15 and the cell 3a to improve the conduction and/or to stabilize the interface to environmental or thermal stresses. The interconnection to the second cell 3b is completed by a conductive tab 25 which contacts both the conductive trace 15 and the back side of cell 3b (i.e., the back side electrode 9 of cell 3b). The tab 25 may be continuous across the width of the cells or may comprise intermittent tabs connected to matching conductors on the cells. The electrical connection can be made with conductive interstitial material, conductive adhesive, solder, or by forcing the tab material 25 into direct intimate contact with the cell or conductive trace. Embossing the tab material 25 may improve the connection at this interface. In the configuration shown in FIG. 3A, the collector-connector 11 extends over the back side of the cell 3b and the tab 25 is located over the back side of cell 3b to make an electrical contact between the trace 15 and the back side electrode of cell 3b. In the configuration of FIG. 3B, the collector-connector 11 is located over the front side of the cell 3a and the tab 25 extends from the front side of cell 3a to the back side of cell 3b to electrically connect the trace 15 to the back side electrode of cell 3b.

In summary, in the module configuration of FIGS. 3A and 3B, the conductor 15 is located on one side of the carrier film 13. At least a first part 13a of carrier 13 is located over a front surface of the first photovoltaic cell 3a such that the conductor 15 electrically contacts the first polarity electrode 7 on the front side of the first photovoltaic cell 3a to collect current from cell 3a. An electrically conductive tab 25 electrically connects the conductor 15 to the second polarity electrode 9 of the second photovoltaic cell 3b. Furthermore, in the module 1a of FIG. 3A, a second part 13b of carrier 13 extends between the first photovoltaic cell 3a and the second photovoltaic cell 3b, such that an opposite side of the carrier 13 from the side containing the conductor 15 contacts a back side of the second photovoltaic cell 3b. Other interconnect configurations described in U.S. patent application Ser. No. 11/451,616 filed on Jun. 13, 2006 may also be used.

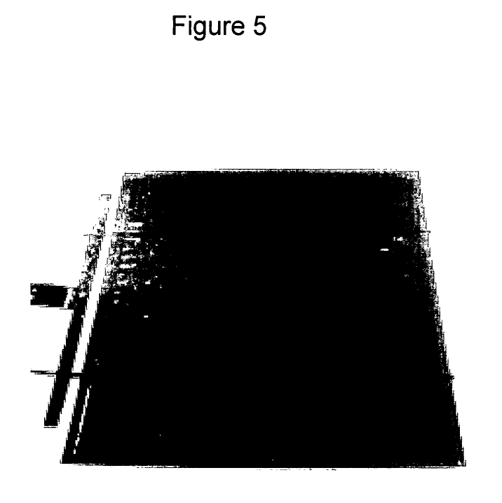

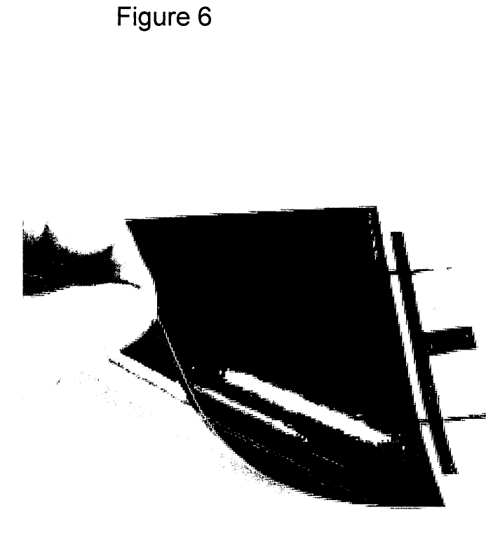

FIGS. 5 and 6 are photographs of flexible CIGS PV cell modules formed on flexible stainless steel substrates. The collector-connector containing a flexible insulating carrier and conductive traces shown in FIG. 3A and described above is formed over the top of the cells. The carrier comprises a PET/EVA co-extrusion and the conductor comprises electrolessly plated copper traces. FIG. 6 illustrates the flexible nature of the cell, which is being lifted and bent by hand.

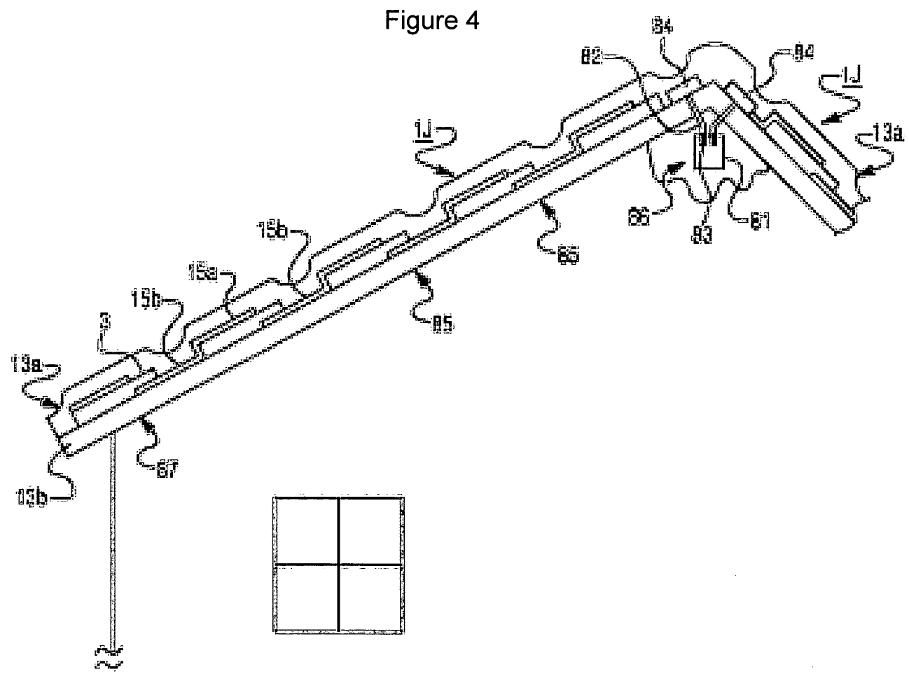

In some embodiments, the collector-connector can include two electrically insulating materials for building integrated photovoltaic (BIPV) applications. FIG. 4 illustrates a photovoltaic module with such collector-connector having a first carrier 13a and a second carrier 13b.

While the carriers 13 may comprise any suitable polymer materials, in one embodiment of the invention, the first carrier 13a comprises a thermal plastic olefin (TPO) sheet and the second carrier 13b comprises a second thermal plastic olefin membrane roofing material sheet which is adapted to be mounted over a roof support structure. Thus, in this aspect of the invention, the photovoltaic module 1j shown in FIG. 4 includes only three elements: the first thermal plastic olefin sheet 13a supporting the upper conductors 15a on its inner surface, a second thermal plastic olefin sheet 13b supporting the lower conductors 15b on its inner surface, and a plurality photovoltaic cells 3 located between the two thermal plastic olefin sheets 13a, 13b. The electrical conductors 15a, 15b electrically interconnect the plurality of photovoltaic cells 3 in the module, as shown in FIG. 4.

Preferably, this module 1j is a building integrated photovoltaic (BIPV) module which can be used instead of a roof in a building (as opposed to being installed on a roof) as shown in FIG. 4. In this embodiment, the outer surface of the second thermal plastic olefin sheet 13b is attached to a roof support structure of a building, such as plywood or insulated roofing deck. Thus, the module 1j comprises a building integrated module which forms at least a portion of a roof of the building.

If desired, an adhesive is provided on the back of the solar module 1j (i.e., on the outer surface of the bottom carrier sheet 13b) and the module is adhered directly to the roof support structure, such as plywood or insulated roofing deck. Alternatively, the module 1j can be adhered to the roof support structure with mechanical fasteners, such as clamps, bolts, staples, nails, etc. As shown in FIG. 4, most of the wiring can be integrated into the TPO back sheet 13b busbar print, resulting in a large area module with simplified wiring and installation. The module is simply installed in lieu of normal roofing, greatly reducing installation costs and installer markup on the labor and materials. For example, FIG. 4 illustrates two modules 1j installed on a roof or a roofing deck 85 of a residential building, such as a single family house or a townhouse. Each module 1j contains output leads 82 extending from a junction box 84 located on or adjacent to the back sheet 13b. The leads 82 can be simply plugged into existing building wiring 81, such as an inverter, using a simple plug-socket connection 83 or other simple electrical connection, as shown in a cut-away view in FIG. 4. For a house containing an attic 86 and eaves 87, the junction box 84 may be located in the portion of the module 1j (such as the upper portion shown in FIG. 4) which is located over the attic 86 to allow the electrical connection 83 to be made in an accessible attic, to allow an electrician or other service person or installer to install and/or service the junction box and the connection by coming up to the attic rather than by removing a portion of the module or the roof.

In summary, the module 1j may comprise a flexible module in which the first thermal plastic olefin sheet 13a comprises a flexible top sheet of the module having an inner surface and an outer surface. The second thermal plastic olefin sheet 13b comprises a back sheet of the module having an inner surface and an outer surface. The plurality of photovoltaic cells 3 comprise a plurality of flexible photovoltaic cells located between the inner surface of the first thermal plastic olefin sheet 13a and the inner surface of the second thermal plastic olefin sheet 13b. The cells 3 may comprise CIGS type cells formed on flexible substrates comprising a conductive foil. The electrical conductors include flexible wires or traces 15a located on and supported by the inner surface of the first thermal plastic olefin sheet 13a, and a flexible wires or traces 15b located on and supported by the inner surface of the second thermal plastic olefin sheet 13b. As in the previous embodiments, the conductors 15 are adapted to collect current from the plurality of photovoltaic cells 3 during operation of the module and to interconnect the cells. While TPO is described as one exemplary carrier 13 material, one or both carriers 13a, 13b may be made of other insulating polymer or non-polymer materials, such as EVA and/or PET for example, or other polymers which can form a membrane roofing material. For example, the top carrier 13a may comprise an acrylic material while the back carrier 13b may comprise PVC or asphalt material.

The carriers 13 may be formed by extruding the resins to form single ply (or multi-ply if desired) membrane roofing and then rolled up into a roll. The grid lines and busbars 15 are then printed on large rolls of clear TPO or other material which would form the top sheet of the solar module 1j. TPO could replace the need for EVA while doubling as a replacement for glass. A second sheet 13b of regular membrane roofing would be used as the back sheet, and can be a black or a white sheet for example. The second sheet 13b may be made of TPO or other roofing materials. As shown in FIG. 4, the cells 3 are laminated between the two layers 13a, 13b of pre-printed polymer material, such as TPO.

The top TPO sheet 13a can replace both glass and EVA top laminate of the prior art rigid modules, or it can replace the Tefzel/EVA encapsulation of the prior art flexible modules. Likewise, the bottom TPO sheet 13b can replace the prior art EVA/Tedlar bottom laminate. The module 1j architecture would consist of TPO sheet 13a, conductor 15a, cells 3, conductor 15b and TPO sheet 13b, greatly reducing material costs and module assembly complexity. The modules 1j can be made quite large in size and their installation is simplified.

### Advantages

The photovoltaic device of the present invention has a number of advantages over prior art photovoltaic devices that utilize luminescence down shifting materials. For example, the photovoltaic device of the present invention can have a flexible substrate unlike the prior art devices that utilize rigid substrates. In addition, the photovoltaic device of the present invention is compatible with a high temperature semiconductor photovoltaic cell deposition as luminescence down shifting materials are incorporated over the photovoltaic cell unlike the prior art devices that incorporate luminescence down shifting materials into a photovoltaic cell. Incorporation of luminescence down shifting materials over the photovoltaic cell allows one to avoid exposing these temperature sensitive materials to high temperatures during the semiconductor deposition process.

The present application incorporates by reference in its entirety U.S. patent application Ser. No. 11/451,616 filed Jun. 13, 2006.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

What is claimed is:

1. A photovoltaic cell comprising
(a) an optically transparent front side electrode;
(b) a back side electrode;
(c) a photovoltaic material having a first side and a second side, the photovoltaic material being disposed between the front side electrode and the back side electrode such that the first side faces the front side electrode and the second side faces the back side electrode;
(d) an insulating layer disposed over the front side electrode,
(e) one or more luminescence down shifting materials facing the first side of the photovoltaic material; and
(f) a substrate facing the second side of the photovoltaic material.

2. The photovoltaic cell of claim 1, wherein the back side electrode comprises portion of the substrate.

3. The photovoltaic cell of claim 2, wherein the substrate is a flexible substrate.

4. The photovoltaic cell of claim 1, comprising two or more luminescence down shifting materials which are mixed together or are located in separate layers.

5. The photovoltaic cell of claim 1, wherein the photovoltaic material comprises a Group I-III-VI semiconductor material.

6. The photovoltaic cell of claim 5, wherein the Group I-III-VI semiconductor material is CuInSe₂ or Cu(In,Ga)Se₂.

7. The photovoltaic cell of claim 1, wherein the insulating layer comprises a polymer material.

8. The photovoltaic cell of claim 1, wherein at least one of the one or more luminescence down shifting materials is located in the insulating layer.

9. The photovoltaic cell of claim 1, wherein at least one of the one or more luminescence down shifting materials is disposed over the front side electrode and below the insulating layer.

10. The photovoltaic cell of claim 1, wherein at least one of the one or more luminescence down shifting materials is disposed over the insulating layer.

11. The photovoltaic cell of claim 1, wherein the one or more luminescent down shifting materials comprise at least one organic dye.

12. The photovoltaic cell of claim 11, wherein the at least one organic dye is selected from naphthalene dyes and perylene dyes.

13. The photovoltaic cell of claim 1, wherein the one or more luminescent down shifting materials comprise at least inorganic phosphor.

14. The photovoltaic cell of claim 1, wherein the one or more luminescent down shifting materials comprise the first material and the second material such that an excitation region of the second material overlaps with an emitting region of the first material.

15. The photovoltaic cell of claim 1, further comprising
a first means for collecting current from the front side electrode;
a second means for electrically connecting the first means to an interconnect through the insulating carrier.

16. A photovoltaic module comprising
a first photovoltaic cell;
a second photovoltaic cell; and
a collector-connector that comprises an insulating carrier and at least one conductor and that is configured to collect current from the first photovoltaic cell and to electrically connect the first photovoltaic cell with the second photovoltaic cell,
wherein at least one of the first photovoltaic cell and the second photovoltaic cell comprises one or more luminescence down shifting material.

17. The photovoltaic module of claim 16, wherein the first photovoltaic cell comprises
(a) a front side electrode;
(b) a back side electrode;
(c) a photovoltaic material having a first side and a second side, the photovoltaic material being disposed between the front side electrode and the back side electrode such that the first side faces the front side electrode and the second side faces the back side electrode;
(d) the insulating carrier disposed on the front side electrode, and
(e) the one or more luminescence down shifting materials facing the first side of the photovoltaic material.

18. The photovoltaic module of claim 17, wherein the back side electrode comprises a substrate.

19. The photovoltaic module of claim 18, wherein the substrate is a flexible substrate.

20. The photovoltaic module of claim 17, wherein the front side electrode is an optically transparent electrode.

21. The photovoltaic module of claim 17, wherein the photovoltaic material comprises a Group I-III-VI semiconductor material.

22. The photovoltaic module of claim 21, wherein the Group I-III-VI semiconductor material is CuInSe₂ or Cu(In,Ga)Se₂.

23. The photovoltaic module of claim 17, wherein at least one of the one or more luminescence down shifting materials is disposed over the front side electrode.

24. The photovoltaic module of claim 16, wherein the insulating carrier comprises a polymer material.

25. The photovoltaic module of claim 16, wherein at least one of the one or more luminescence down shifting materials is located in the insulating carrier.

26. The photovoltaic module of claim 16, wherein at least one of the one or more luminescent down shifting materials is disposed over the insulating carrier.

27. The photovoltaic module of claim 16, wherein the one or more luminescent down shifting material comprise at least one organic dye.

28. The photovoltaic module of claim 27, wherein the at least one organic dye is selected from naphthalene dyes and perylene dyes.

29. The photovoltaic module of claim 16, wherein the one or more luminescent down shifting materials comprise at least inorganic phosphor.

30. The photovoltaic module of claim 16, wherein the one or more luminescent down shifting materials comprise the first material and the second material such that an excitation region of the second material overlaps with an emitting region of the first material.
